(19) United States
(12) Patent Application Publication
(10) Pub. No.: US 2007/0221402 A1
(43) Pub. Date: Sep. 27, 2007

(54) Soft wire bank joint device

(76) Inventor: Alex Huang, Taipei Country (TW)

Correspondence Address: ALEX HUANG, 235 Chung - Ho, Box 8-24, Taipei, TW

(21) Appl. No.: 11/385,605

(22) Filed: Mar. 22, 2006

(51) Int. Cl. H05K 1/16

(52) U.S. Cl. 174/260

(57) ABSTRACT

A soft wire bank joint device comprises a body and a joint connected to one end of the body; the body including: a first insulating layer; a conductive wire layer located above the first insulating layer; a second insulating layer located above the conductive wire layer; a silver shielding layer located above the second insulating layer; and a third insulating layer located above the silver shielding layer. The joint includes a top sheet, a bottom sheet and an insulating casing. One end of the body is installed on the bottom sheet; and the bottom sheet is installed on the insulating casing. The top sheet is coupled to the insulating casing. A length of the second insulating layer is equal to that of the silver shielding layer, but is shorter than that of the conductive wire layer. One side of the conductive wire layer projects out from the second insulating layer.

### FIELD OF THE INVENTION

The present invention relates to joints, and in particular to a soft wire bank joint device for connecting electron devices to circuit boards.

### BACKGROUND OF THE INVENTION

Soft wire bank joint devices are used to electrically connect an electronic device to a circuit board for transmission of signals.

Referring to FIG. 1, a prior art soft wire bank joint device is illustrated. The soft wire bank joint device includes a receptacle 1 and a soft wire bank. The receptacle includes a body 11 which is enclosed by a metal casing, an upper terminal 12 which is inserted into an upper insertion portion of the body 11, and a lower terminal 13 which is inserted into a lower insertion portion of the body 11. The upper terminal 12 has a cambered contact portion 121 and the lower terminal 13 has a cambered contact portion 131.

A joint 2 serves to electrically connect to the receptacle 1. The joint 2 has an insulating body 21, a top sheet 22, and a lower sheet 23. The top sheet 22 is installed at the topside of the insulating body 21 and the lower sheet 23 is installed at the lower side of the insulating body 21. Each has a cured contact portions 121, 131.

The joint 2 is electrically inserted into the receptacle 1. The joint 2 includes an insulating body 21, a top sheet 22 and a bottom sheet 23 which are installed at the top and bottom sides of the insulating body 21. A soft wire bank 3 is adhered between the top sheet 22 and the insulating body 22 or between the bottom sheet 23 and the insulating body 22 so that one contact point of the body 3 protrudes from the joint 2.

Other than a pull sheet 33, the soft wire bank 3 is installed with a silver layer which is formed as a contact net surface 32. The surface 32 electrically contacts with the top sheet 22 or the bottom sheet 23 for lowering electromagnetic interference.

However the contact net surface 32 at one side of the soft wire bank 3 is directly protruded out. The contact net surface 32 is conductive. As a result it is easy to have fault in conduction.

### SUMMARY OF THE INVENTION

Accordingly, the primary object of the present invention is to provide a soft wire bank joint device for connecting electron devices to circuit boards. The present invention can avoid the defect in the prior art.

To achieve above objects, the present invention provides a soft wire bank joint device which comprises a body and a joint connected to one end of the body; the body including: a first insulating layer; a conductive wire layer above the first insulating layer; a second insulating layer above the conductive wire layer; a silver shielding layer above the second insulating layer; and a third insulating layer above the silver shielding layer. The joint includes a top sheet, a bottom sheet and an insulating casing. One end of the body is installed on the bottom sheet; and the bottom sheet is installed on the insulating casing. The top sheet is coupled to the insulating casing. A length of the second insulating layer is equal to that of the silver shielding layer, but is shorter than that of the conductive wire layer. One side of the conductive wire layer projects out from the second insulating layer.

The various objects and advantages of the present invention will be more readily understood from the following detailed description when it is read in conjunction with the appended drawings.

### BRIEF DESCRIPTION OF THE DRAWINGS

FIG. 1 is an exploded schematic view about the prior art soft bank wire connector.

FIG. 2 is an exploded perspective view of the soft wire bank joint device of the present invention.

FIG. 3 is an assembled perspective view of the soft wire bank joint device of the present invention.

FIG. 4 is a backside view of the soft wire bank joint device of the present invention.

FIG. 5 is a backside view of the soft wire bank joint device of the present invention.

FIG. 6 is a partial enlarged view of the soft wire bank joint device of the present invention, which is viewed along line 6-6 of FIG. 4.

FIG. 7 is a cross sectional view of the soft wire bank joint device of the present invention, which is viewed along line 7-7 of the present invention.

FIG. 8 is an exploded perspective view of the soft wire bank joint device of the present invention after the structure is assembled.

FIG. 9 is a perspective view of the soft wire bank joint device of the present invention, which is assembled according to FIG. 8.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

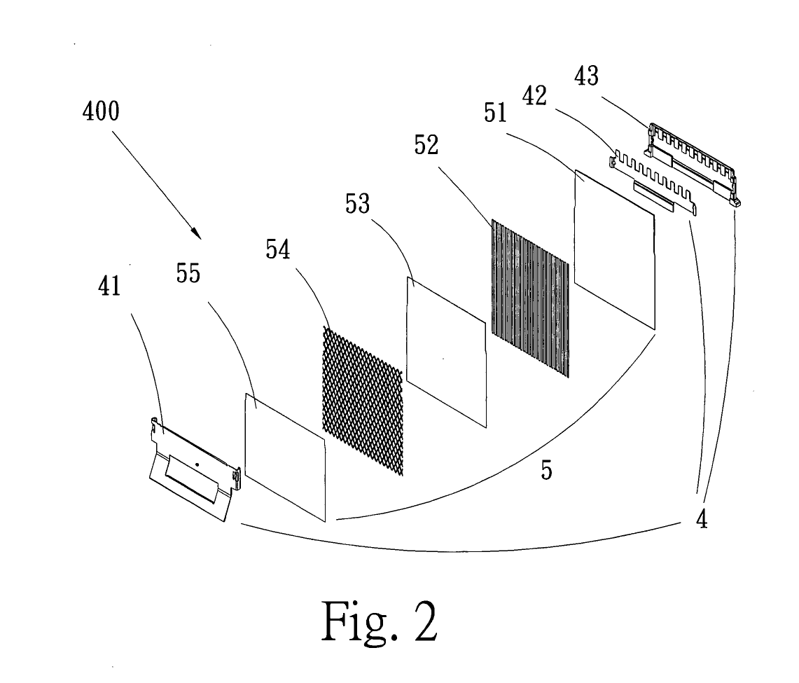

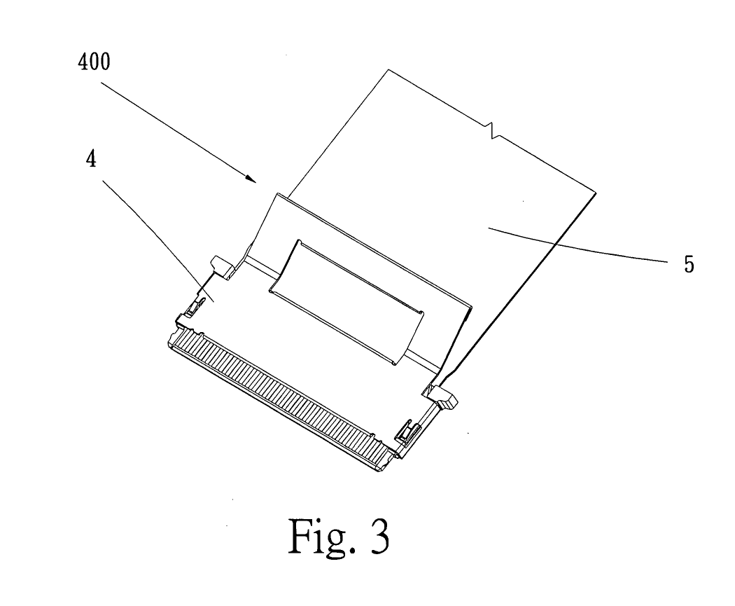

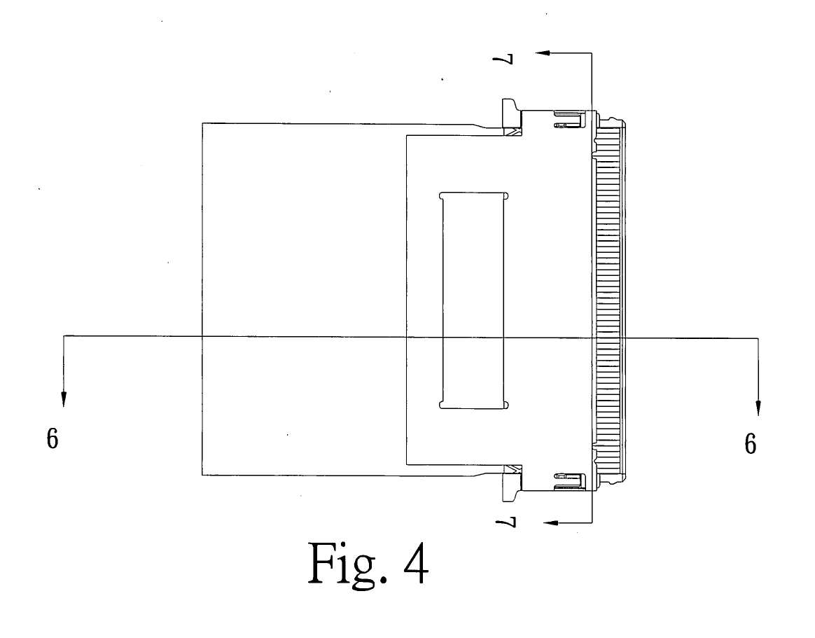

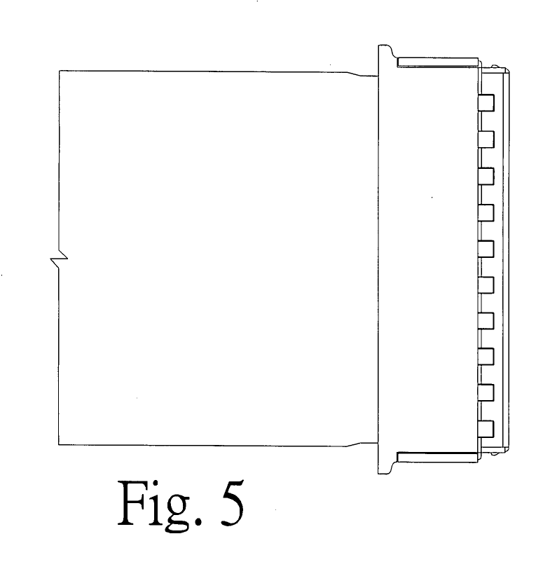

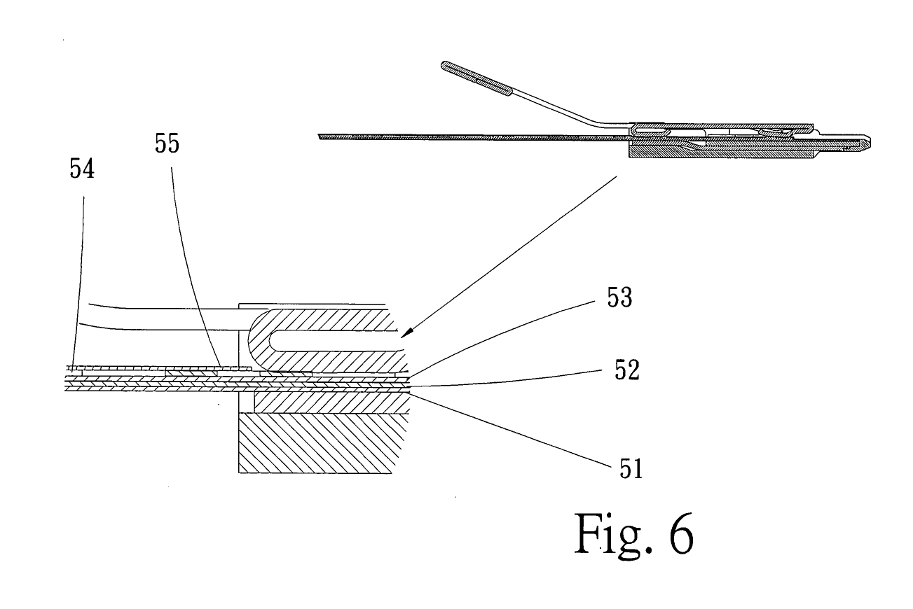

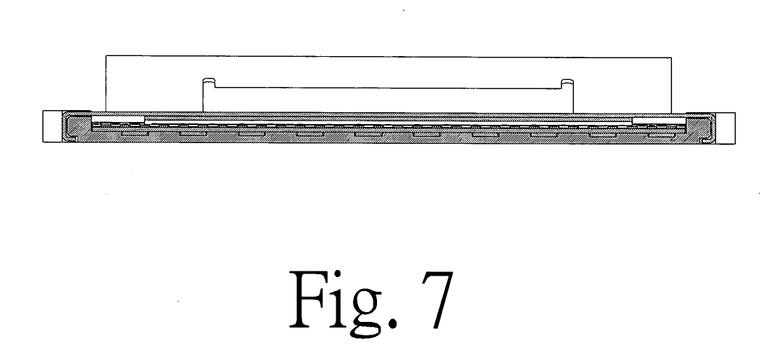

Referring to FIGS. 2 to 9, the soft bank wire device of the present invention is illustrated. The present invention has the following elements.

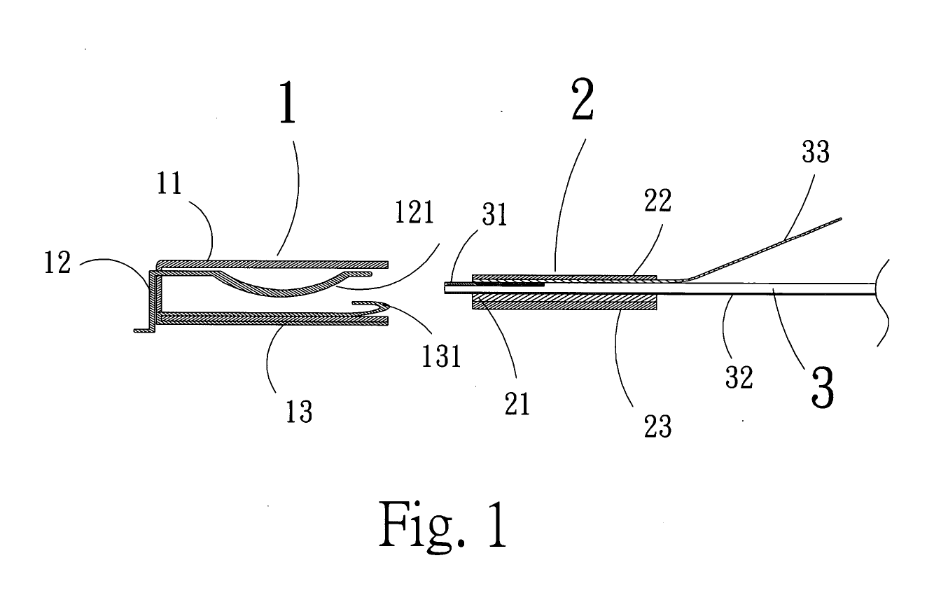

A receptacle (as illustrated in FIG. 1) and a soft bank wire unit 400. The soft bank wire unit 400 has a joint 4 and a soft bank wire body 5.

The joint 4 includes a top sheet 41, a bottom sheet 42 at a lower side of the top sheet 41 and an insulating casing 43. A pull portion 411 extends from the top sheet 41. The user can pull the pull portion 411. The bottom sheet 42 has a receiving portion 421. The insulating casing 43 is formed with a receiving portion 431. The bottom sheet 42 is received in the receiving portion 431 and the top sheet 41 is protruded out from the insulating casing 43.

The soft bank wire body 5 includes a first insulating layer 51, a conductive wire layer 52, a second insulating layer 53, a silver shielding layer 54 and a third insulating layer 55 which are sequentially arranged. The second insulating layer 53 and the silver shielding layer 54 have the same length and are shorter than the length of the conductive wire layer 52. A length of the third insulating layer 55 is shorter than that of the silver shielding layer 54.

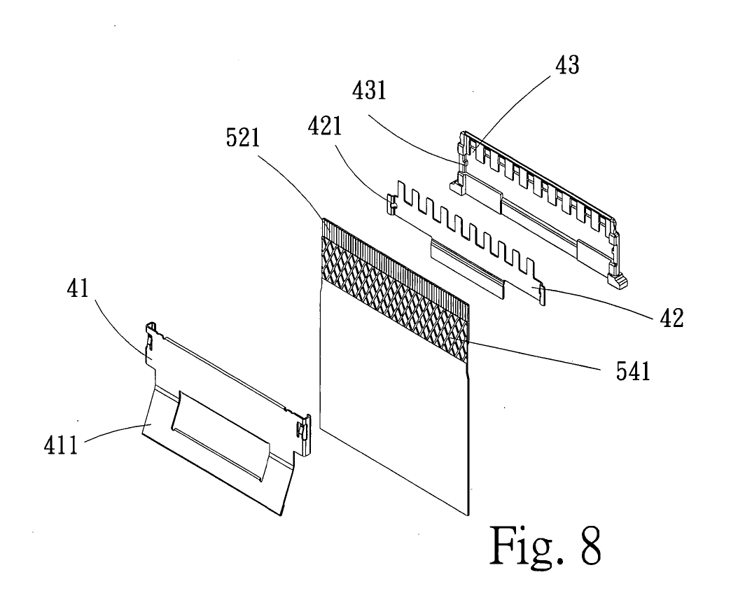

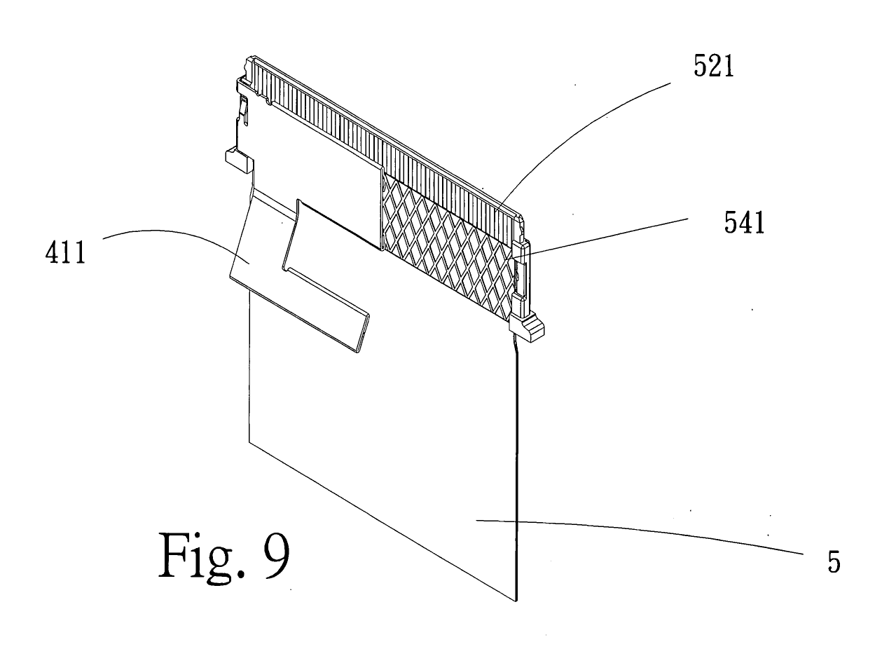

Referring to FIGS. 8 and 9, an end portion of the conductive wire layer 52 is extended with a projection 521 for electric connection. One end portion of the silver shielding layer 54 is formed with a projection 541. The top sheet 41 of the joint 4 is electrically connected to the projection 541. Other portions of the silver shielding layer 54 are not projected out so as not to contact other objects.

One end of the soft bank wire body 5 is received into the receiving portion 421 of the bottom sheet 42.

The third insulating layer 55 is hidden other than the projection 541 of the third insulating layer 55. The projection 541 serves to contact the top sheet 41. Thereby the silver shielding layer 54 will not have fault contact.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A soft wire bank joint device comprising:
a body and a joint connected to one end of the body; the body including:
a first insulating layer;
a conductive wire layer located above the first insulating layer;
a second insulating layer located above the conductive wire layer;
a silver shielding layer located above the second insulating layer; and
a third insulating layer located above the silver shielding layer.

2. The soft wire bank joint device as claimed in claim 1, wherein the joint includes a top sheet, a bottom sheet and an insulating casing; one end of the body is installed on the bottom sheet; and the bottom sheet is installed on the insulating casing; and the top sheet is coupled to the insulating casing.

3. The soft wire bank joint device as claimed in claim 2, wherein a top sheet of the joint is protruded with a pull portion.

4. The soft wire bank joint device as claimed in claim 1, wherein a length of the second insulating layer is equal to that of the silver shielding layer, but is shorter than that of the conductive wire layer; one side of the conductive wire layer projects out from the second insulating layer.

5. The soft wire bank joint device as claimed in claim 1, wherein a length of the third insulating layer is shorter than that of the silver shielding layer; and one side of the silver shielding layer projects out from the third insulating layer.

6. The soft wire bank joint device as claimed in claim 5, wherein the joint includes a top sheet, a bottom sheet and an insulating casing; one end of the body is installed on the bottom sheet; and the bottom sheet is installed on the insulating casing; the top sheet is coupled to the insulating casing; and the top sheet electrically contacts a projection portion of the silver shielding layer.
